(19) United States
(12) Patent Application Publication
(10) Pub. No.: US 2011/0102331 A1
(43) Pub. Date: May 5, 2011

(54) REDUNDANT TOUCHSCREEN ELECTRODES

(75) Inventor: Harald Philipp, Hamble (GB)

(73) Assignee: QRG LIMITED, LONDON (GB)

(21) Appl. No.: 12/608,802

(22) Filed: Oct. 29, 2009

(51) Int. Cl. G06F 3/041; H05K 13/04

(52) U.S. Cl. 345/173; 29/832

(57) ABSTRACT

A touchscreen display assembly has a substrate and a plurality of electrodes distributed across at least an active area of the substrate. At least one of the electrodes comprises a group of redundant electrode lines electrically coupled to an external electrical circuit connection and further coupled to one another remote from the external electrical circuit connection.

### FIELD

The invention relates generally to touchscreens, and more specifically to redundant electrodes in a touchscreen.

### BACKGROUND

Touchscreen displays are able to detect a touch within the active or display area, such as detecting whether a finger is present pressing a fixed-image touchscreen button or detecting the presence and position of a finger on a larger touchscreen display. Some touchscreens can also detect the presence of elements other than a finger, such as a stylus used to generate a digital signature, select objects, or perform other functions on a touchscreen display.

Use of a touchscreen as part of a display allows an electronic device to change a display image, presenting different buttons, images, or other regions that can be selected, manipulated, or actuated by touch. Touchscreens can therefore provide an effective user interface for cell phones, GPS devices, personal digital assistants (PDAs), computers, ATM machines, and other devices.

Touchscreens use various technologies to sense touch from a finger or stylus, such as resistive, capacitive, infrared, and acoustic sensors. Resistive sensors rely on touch to cause two resistive elements overlaying the display to contact one another completing a resistive circuit, while capacitive sensors rely on the capacitance of a finger changing the capacitance detected by an array of elements overlaying the display device. Infrared and acoustic touchscreens similarly rely on a finger or stylus to interrupt infrared or acoustic waves across the screen, indicating the presence and position of a touch.

Capacitive and resistive touchscreens often use transparent conductors such as indium tin oxide (ITO) or transparent conductive polymers such as PEDOT to form an array over the display image, so that the display image can be seen through the conductive elements used to sense touch. The size, shape, and pattern of circuitry have an effect on the accuracy of the touchscreen, as well as on the visibility of the circuitry overlaying the display. Although a single layer of most suitable conductive elements is difficult to see when overlaying a display, multiple layers can be visible to a user, as can large elements using more opaque materials such as metals.

Metal wire and fine metal lines are therefore used as touchscreen elements or electrodes in some touchscreen designs, often having widths on the order of single or double digit microns in width to reduce visibility. Although lines having lower widths are less visible, they are more prone to manufacturing defects or breakage due to their reduced size. Because there is a tradeoff between visibility and yield or durability of fine line metal electrodes, it is desirable to consider efficient and effective design of such electrodes when designing a touchscreen display.

### SUMMARY

A touchscreen assembly has a substrate and electrodes distributed across an active touchscreen area of the substrate. At least one of the electrodes includes a redundant pair of electrode lines electrically coupled to one another at multiple points along the electrode lines. In a further example, the redundant pair of electrodes are fine metal lines that are substantially parallel, and 10 micrometers or under in width.

### BRIEF DESCRIPTION OF THE FIGURES

FIG. 1 shows a two-layer mutual capacitance touchscreen assembly, consistent with the prior art.

FIG. 2 illustrates an example touchscreen electrode configuration, consistent with the prior art.

FIG. 3 shows the touchscreen electrode arrangement of FIG. 2 including parallel redundant fine line metal electrodes, consistent with an example embodiment.

FIG. 4 shows the example two-layer mutual capacitance touchscreen configuration of FIG. 1 incorporating parallel redundant fine line metal electrodes, consistent with an example embodiment.

FIG. 5 shows an alternate parallel redundant fine line metal electrode configuration, consistent with an example embodiment.

FIGS. 6A and 6B illustrate a touchscreen display assembly, consistent with an example embodiment.

FIG. 7 shows a cellular telephone having touchscreen display, consistent with an example embodiment.

### DETAILED DESCRIPTION

Touchscreens are often used as interfaces on small electronic devices, appliances, and other such electronic systems because the display behind the touchscreen can be easily adapted to provide instruction to the user and to receive various types of input, thereby providing an intuitive interface that requires very little user training to use effectively. Inexpensive and efficient touchscreen technologies enable incorporation of touchscreens into inexpensive commercial devices, but these inexpensive technologies should also desirably be durable and have relatively high immunity to noise, moisture or dirt, or other unintended operation to ensure reliability and longevity of the touchscreen assembly. Further, the touchscreen technology desirably causes minimal interference with an underlying display, enabling a displayed image to be viewed undistorted through the touchscreen.

Touchscreen displays are often therefore formed of relatively narrow electrodes, such as metal wires or fine metal lines, that are difficult to see when overlaying a displayed image. The configuration of electrodes varies significantly between designs, and includes single and multi-layer touchscreens, self-capacitance and mutual-capacitance touchscreens, and a wide variety of electrode patterns.

In a typical mutual capacitance touchscreen, the capacitance between drive electrodes and various receive or sense electrodes is monitored, and a change in mutual capacitance between the electrodes indicates the presence and position of a finger. Mutual capacitance sensor circuitry measures the capacitance between the drive electrodes and the receive electrodes, which are covered by a dielectric overlay material that provides a sealed housing. When a finger is present, field coupling between the drive and receive electrodes is attenuated, as the human body conducts away a portion of the field that arcs between the drive and receive electrodes. This reduces the measured capacitive coupling between the drive and receive electrodes.

Similarly, when a finger approaches a self-capacitance touchscreen electrode, the finger capacitively couples with the touchscreen electrode and the resulting increase in measured capacitance of the self-capacitance electrode is detected by the touchscreen circuitry.

The touchscreen electrodes that overlay a display are typically formed from conductive materials such as metal wire traces or fine line metal, or conductors such as Indium tin oxide which are transparent and relatively conductive in thin layers. Other materials such as PEDOT (polyethylene dioxythiophene), conductive inks, and other conductive polymers are also relatively transparent and used in some touchscreens.

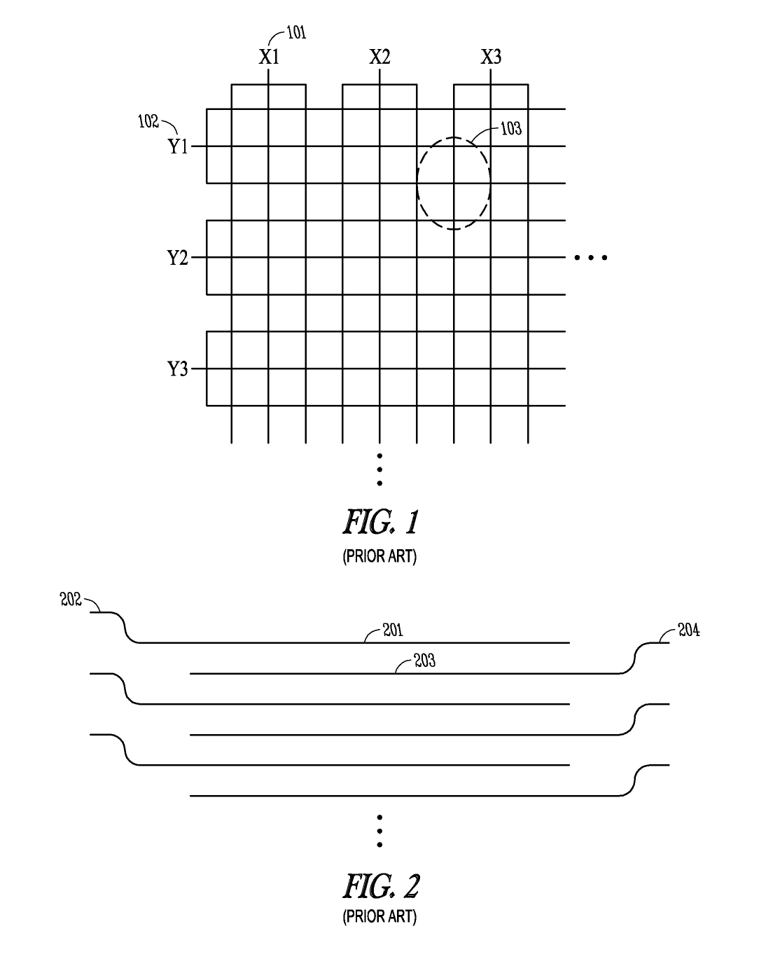

An example touchscreen shown in FIG. 1 uses an array of conductive traces as touchscreen electrodes, having X and Y electrodes in different layers. The electrodes in this example are distributed across the touchscreen display approximately evenly, and are divided into different electrodes 1-3 for both the X and Y electrode lines.

When used in a mutual-capacitance mode, three different drive signals X1-X3 drive the three separate arrays of vertical X drive electrodes, as shown generally at 101. The signals driving these lines capacitively couple with the horizontal receive electrodes Y1-Y3, shown at 102. When a finger touches the touchscreen such as at location 103, the finger desirably interacts with several electrodes, intersecting the X2 and X3 drive electrodes and Y1 and Y2 receive electrodes such that the finger's position on the touchscreen can be determined by the degree of interference with capacitive coupling of each drive and receive zone.

When operated as a mutual capacitance touchscreen, different series of pulses are sent via the X1-X3 drive lines, such that the mutual capacitance between the different X drive lines and Y receive lines can be separately determined such as by observation of a change in RC time constant or another suitable method. When the presence of a finger interrupts the field between the X and Y drive and receive lines, such as by coming in close proximity to a portion of the touchscreen, a reduction in observed capacitance between the electrodes is observed.

A finger touching region 103 interferes with capacitive coupling between the X3 drive electrodes and the receive electrodes somewhat more than it interferes with coupling between the X2 drive electrodes and the receive electrodes, and similarly interferes with coupling between the Y1 receive electrode and the drive electrodes somewhat more than it interferes with capacitive coupling between the Y2 receive electrode and drive electrodes. This indicates that the finger's touch is located between X2 and X3 but somewhat closer to X3, and between Y1 and Y2 but somewhat closer to Y1 on the grid formed by the drive and receive electrodes.

When operated as a self-capacitance touchscreen, a finger touching region 103 increases the measured self-capacitance of the electrodes X3 and X2, and increases the measured self-capacitance of electrodes Y1 and Y2, similarly indicating the finger's two-dimensional position on the electrode grid.

Although each electrode in this example comprises multiple lines, in other examples, each electrode may have a single line, a greater number of lines, or some other geometric configuration. The touchscreen display of FIG. 1 is shown having three different vertical electrodes and three different horizontal electrodes, but other embodiments, such as a typical computer or smart phone application, may have significantly more electrodes than shown in this example.

The finger's influence on multiple electrodes enables the touchscreen display to detect the vertical and horizontal position of a finger on the touchscreen display with very good accuracy, well beyond simply determining in which of the three shown vertical and horizontal regions the finger is located. To achieve this result, the electrode line spacing here is configured anticipating a fingerprint that is approximately 8 mm from top to bottom. In this example, the lines are spaced approximately 2 mm apart, such that a typical touch interacts strongly with at least three or four vertical and horizontal lines.

FIG. 2 shows another example touchscreen electrode arrangement, consistent with the prior art. Here, an array of touchscreen electrodes such as 201 and 203 are configured with alternating external electrical connections, such as electrode 201's connection 202 to the left of the touchscreen and electrode 203's connection 204 to the right of the touchscreen. The connections 202 and 204 are not a part of the active touchscreen area, but serve to couple the electrodes to external circuitry. Although a group of electrodes is shown here, other electrodes and connections will typically be required to form a useful touchscreen device, including in some embodiments additional electrode layers electrically isolated from the layer shown. Some electrode configurations such as the example shown here can be created with a single layer, resulting in reduced cost due to manufacturing efficiency. Various patterns of drive electrodes or drive and receive electrodes can be used to create a variety of self-capacitance or mutual-capacitance touchscreens, using relatively narrow electrode lines such as fine line metal electrodes or metal wire.

If the lines are formed of material that is particularly thin or narrow, as is often desired so that the lines are not visible to a user, the lines may be subject to occasional manufacturing defects or breakage, limiting the touchscreen's ability to accurately identify the position of a touch in the area of the broken or damaged electrode. Fine line metal elements used in one example embodiment are 10 micrometers or less in line width, at a line density of 7 percent or less of the total screen area. Because fine line metal traces often have widths on the order of single digit microns in width to reduce visibility, susceptibility to manufacturing defects or breakage due to their reduced size becomes a design concern.

Breakage of fine line metal electrodes on the order of ones of microns can occur during production as a result of handling, dust, or other contamination. Similarly, dirt or dust on the photo mask can cause defects when used to print fine line metal elements using lithography or other similar processes, resulting in unintentional open circuits in fine lines. As the line widths become smaller, their susceptibility to physical damage and breakage due to other factors such as mask flaws becomes greater, making integrity of fine line metal a greater concern as line widths shrink.

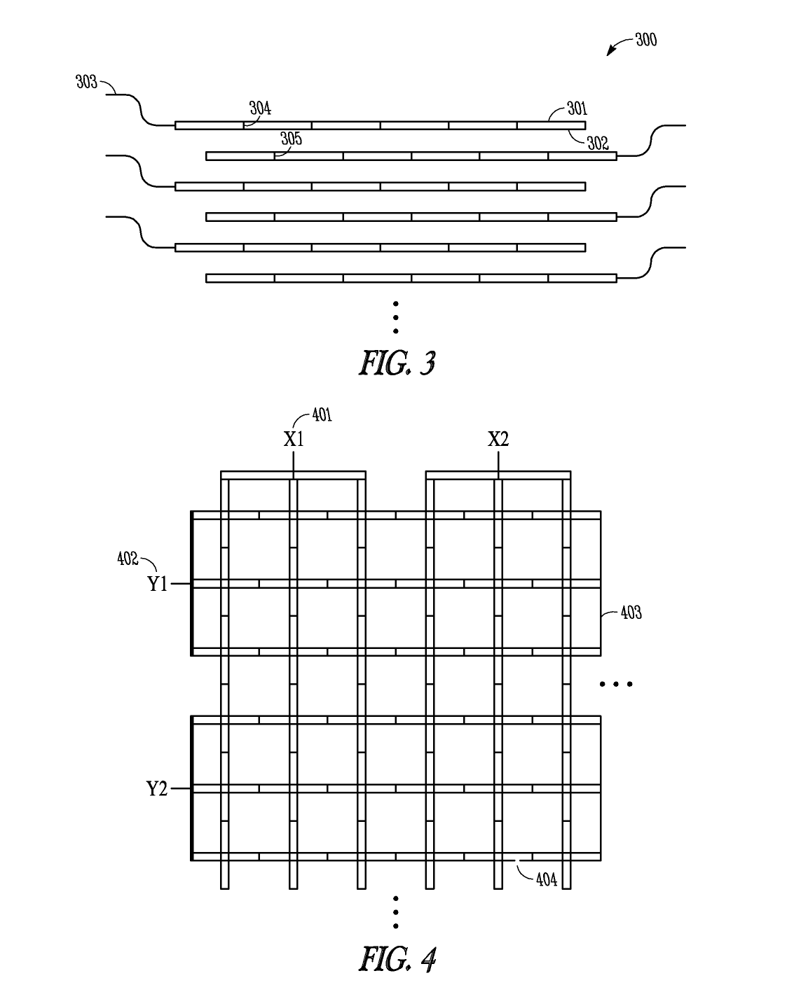

One example embodiment of the invention therefore seeks to provide high durability and yield while using thin fine line metal electrodes by providing internal redundancy. FIG. 3 shows an example embodiment of a touchscreen electrode array using redundant electrodes connected at multiple points. The electrode configuration shown here generally at 300 corresponds to the electrode configuration of FIG. 2, but each electrode of FIG. 2 is supplemented with a substantially parallel second electrode coupled at multiple points. For example, electrode 301 is near and substantially parallel to electrode 302, and the electrodes 301 and 302 are coupled at both the external connection 303 and at the end of the lines opposite the external connection. Further, a number of “ladder rung” or intermediate bridges are formed between the electrodes as shown at 304 and 305.

The bridging elements 304 and 305 are staggered in this example, such that they do not align vertically and contribute to visible vertical banding when overlaying a touchscreen display. In other embodiments, the bridging elements are randomized, angled, curved, or otherwise configured to link redundant electrodes so that they do not contribute to visible artifacts when overlaying a touchscreen display.

Because the redundant fine line metal touchscreen elements are linked in multiple locations, including at the external circuit connection and at the end of the electrodes furthest from the external circuit connection, the redundant pair of electrodes can sustain a single break at any point and remain fully electrically coupled.

More specifically, with each of a pair of closely spaced, parallel electrodes coupled together and to an external circuit at only one end, a single fault in either electrode would leave the remaining electrode intact, and operable to drive or sense an electric signal over its length. But, if one of the pair of redundant electrodes fails near its connection to external circuitry, the majority of one of the redundant pair of electrodes will not be connected to the external circuitry, leaving only the second electrode to drive or receive a touchscreen sensing signal. Because it is desirable to have electrodes emit and sense signals in fixed strengths or proportions, the parallel pair of redundant electrodes may also be linked at their far ends most remote from the external circuit connection as well, ensuring conductivity through both electrodes in the pair in the event of a single electrical open fault in either electrode. For example, the electrode 301 of FIG. 3 could be formed as a pair of redundant electrode lines bridged at either end, forming a long rectangle with no ladder rung bridging elements.

In the example electrode 301 shown in FIG. 3, additional bridging connections 304 between the redundant electrodes are used, such that the redundant parallel electrodes resemble a ladder having widely spaced rungs. This serves to provide resiliency against some instances of multiple open defects along the electrodes. As long as no more than one break occurs in either of the redundant parallel lines between ladder segments or other connections between the redundant electrodes, the connections between the electrodes will ensure that both electrodes remain fully connected to the external circuitry.

This provides greater robustness against randomly distributed defects such as dust particles on the substrate or mask, and against local breakage of one of the pair of electrodes. The greater the number of ladder elements the more resistant the redundant lines will be to multiple open circuit defects, but at the cost of a greater metal density in the touchscreen active area and specifically in the region of the redundant line pair. In a more detailed example, the spacing between ladder rungs is therefore large relative to the line width, such as ladder elements every 1 mm with fine line metal elements on the order of 10 micrometers in width.

The defect rate of the selected line width and manufacturing process can be used to statistically model or experimentally determine the likelihood of multiple breaks in the same portion of the redundant electrodes between any two bridging segments, and can be used to predict yields or make design choices based on acceptable yield rates.

Including ladder or bridge connections between the redundant parallel electrodes can also reduce the resistance between the external electrical connection and the break point. Consider an example lacking ladder rungs or bridges except at the electrode ends where one of a pair of electrodes is broken near the external electrical connection, and the only remaining electrical path to energize the broken electrode to the break is through nearly the entire length of both redundant electrodes. Considering the narrow width and relatively long length of the electrodes, ladder elements can significantly reduce the resistance to the break by providing an alternate path to the break much nearer the external electrical connection than the opposite end of the redundant electrode pair.

In a more detailed example, the fine line metal elements are desirably under 10 micrometers in width, so that the lines are practically invisible to a user when overlaying a display. The total line density is further desirably under 10%, so that the overlaying touchscreen line elements do not cause a noticeable reduction in brightness of the display. For example, a design may comprise lines that are 5 micrometers in width, targeting 5% line density in the position-sensitive touchscreen region of the display.

Similarly, it is desirable to manage the distance between the redundant pair of electrode lines, so that they do not appear to be a single, larger line when viewed overlaying a display. As previously discussed, lines greater than about 10 micrometers (μm) in width can be visible to a user, so it is particularly desirable when using electrode lines that are 5-10 μm in width to space the lines substantially farther apart than the electrode line width to prevent them from effectively appearing to be a single larger line. It is also desirable in some applications to keep the lines relatively close together, so that they are effectively in the same location for purposes of determining touch position. In one design example, the distance between lines is a fixed distance such as 100 to 200 micrometers, while in another design the distance between line elements is a multiple of the fine line element width, such as 5× - - - 50×, 10×, or some other multiple of the line width.

As shown in FIG. 3, redundant paths formed by coupled pairs of fine line metal elements can provide a degree of robustness against open defects in line electrodes in touchscreen displays. FIG. 4 illustrates an electrode pattern such as was illustrated in FIG. 1, but using redundant line electrodes rather than single electrode lines. Here, X electrodes as shown at 401 each have three pairs of redundant electrode lines, including bridges across the electrode lines at frequent intervals. An array of Y electrodes overlay the X electrodes in a direction substantially orthogonal to the X electrode lines as shown at 402, enabling position to be determined in two dimensions. The electrodes may be in one or two layers, such that the layers are electrically isolated from each other.

FIG. 4 also illustrates a variety of ways of linking redundant pairs of electrodes coupled to the same external electrical connection. The Y1 electrical connection shown at 402 uses a wide metal crossbar to distribute the electrical signal to the three Y1 pairs of redundant electrode lines, such that the wide metal bar is less likely to suffer from an open circuit defect than the thinner electrode lines. A single thin line is used to electrically couple the far end of the Y1 electrode pairs at 403, but is more susceptible to failure due to a defect in the line. The X1 electrode group at 401 is linked by a crossbar formed as a redundant electrode pair, such as is used to form the electrode lines. The wide metal crossbar shown at 402 is suitable for linking the connected or far end of linked electrode pairs when the crossbar is not in the active area of the touchscreen, but may be visible if used in the active touchscreen area. A fine metal line structure such as the redundant electrode pair crossbar shown at 401 may therefore be desired to link electrode pairs in the touchscreen's active area.

A break is shown at 404 in the example of FIG. 4, illustrating how the redundant electrode above the break and the ladder rung bridging elements to either side of the break form a cell that serves to provide redundant electrical connection to the electrode on both sides of the break. An electrode configuration such as that of FIG. 4 can tolerate up to one such break per cell, and can tolerate multiple breaks per cell in some locations due to the redundancy provided by the crossbars such as 403 linking the three pairs of electrodes at each end.

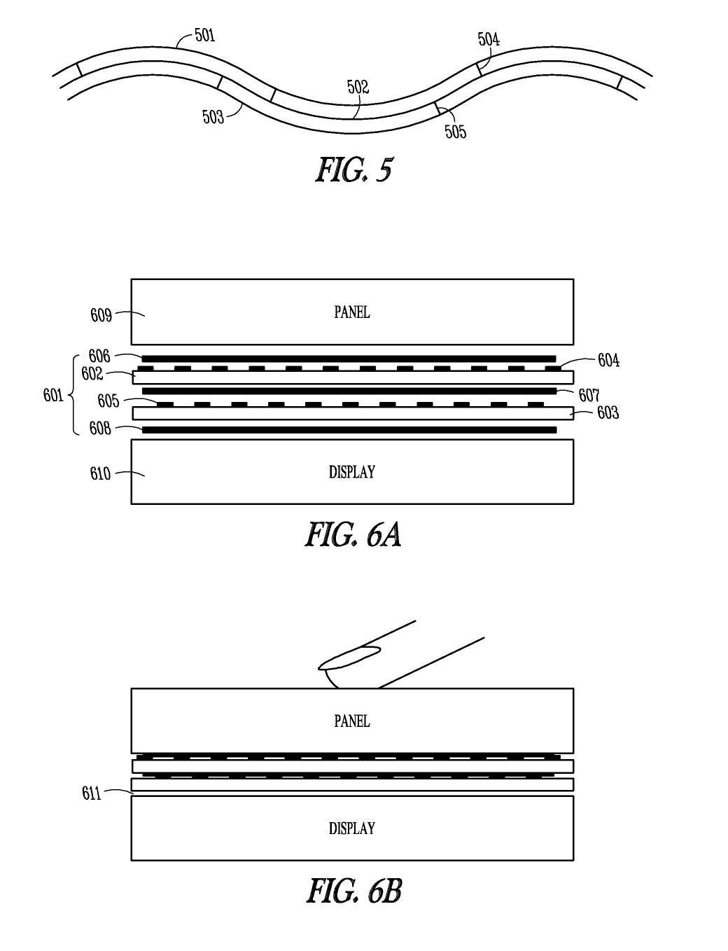

FIG. 5 illustrates an alternate electrode configuration, comprising a group of three redundant wavy line electrodes linked by bridging elements at various points along the electrode lengths. In this example, bridging elements between top electrode line 501 and middle electrode line 502 do not align with the bridging elements linking middle electrode line 502 with bottom electrode line 503, as shown at 504 and 505. By spacing the bridging elements apart from one another vertically and horizontally, chances of creating visible artifacts when an array of touchscreen electrodes overlay a display are reduced. The wavy electrode line pattern similarly contributes to reducing the visibility of the touchscreen electrode pattern.

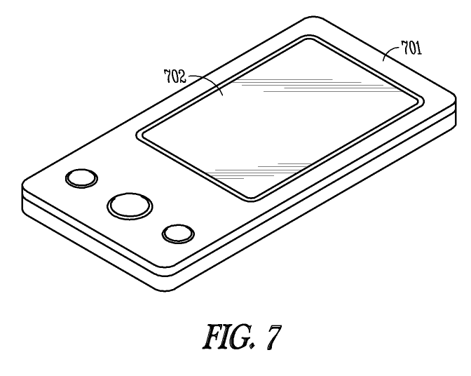

A touchscreen display panel such as that of FIG. 4 can be used to overlay a display, such as a liquid crystal display or OLED display, as shown in FIG. 6A. The touchscreen assembly stack 601 contains two sensing layers, for example as may be used to implement a two-layer touchscreen design such as is shown in FIG. 4. Two layers of plastic film are used, 602 and 603, with respective electrodes 604 and 605 fashioned thereon, and assembled with adhesive layers 606, 607 and optionally 608 via a lamination process to panel 609 and possibly also to display 610. Electrodes such as 604 and 605 are formed in different ways in various embodiments, including inkjet printing of conductive or metallic ink, various other metal printing or lithography processes, and other suitable technologies.

FIG. 6B shows the layer stack of FIG. 6A as laminated together, but without the adhesive layer 608, using instead an airgap 611.

Touchscreen displays such as shown in FIG. 6B are often used in a variety of applications, such as automatic teller machines (ATM machines), home appliances, personal digital assistants and cell phones, and other such devices. One such example cellular telephone and PDA device is illustrated in FIG. 7. Here, the cellular telephone device 701 includes a touchscreen display 702 comprising a significant portion of the largest surface of the device. The large size of the touchscreen enables the touchscreen to present a wide variety of data, including a keyboard, a numeric keypad, program or application icons, and various other interfaces as desired.

The user may interact with the device by touching with a single finger, such as to select a program for execution or to type a letter on a keyboard displayed on the touchscreen display assembly 702, or may use multiple touches such as to zoom in or zoom out when viewing a document or image. In other devices, such as home appliances, the display may not change or may change only slightly during device operation, and may recognize only single touches.

Although the example touchscreen display of FIG. 4 is configured as a rectangular grid, other configurations are within the scope of the invention, such as a touchwheel, a linear slider, buttons with reconfigurable displays, and other such configurations. Redundant fine line metal electrodes to provide open fault resiliency can be applied to any such configuration, and the invention is not limited to the example configurations presented here.

Many materials will be suitable for forming touchscreens such as those described herein, and materials may be mixed within a single assembly. For example, transparent Indium tin oxide, fine line metal, conductive polymers or inks, and other materials may be used in various combinations to form touchscreens such as those illustrated in the drawings. In many embodiments, it is desirable that the conductive material be either transparent, such as Indium tin oxide or transparent conductive polymer, or be so small as to not significantly interfere with visibility of the display, such as with the fine metal line electrodes discussed here.

Fine line metal wires in a further example are used not only for conductivity enhancement of touchscreen electrodes, but for electrical connections to and between the various electrodes.

Although the fine line metal conduction-enhanced touchscreen display elements in the preceding examples given here generally rely on self capacitance or mutual capacitance to operate, other embodiments of the invention will use other technologies, including other capacitance measures, resistance, or other such sense technologies.

These example touchscreen assemblies illustrate how redundant pairs of fine line metal elements can be used to circumvent line breaks at one or more points. Although specific embodiments have been illustrated and described herein, it will be appreciated by those of ordinary skill in the art that any arrangement that achieve the same purpose, structure, or function may be substituted for the specific embodiments shown. This application is intended to cover any adaptations or variations of the example embodiments of the invention described herein. It is intended that this invention be limited only by the claims, and the full scope of equivalents thereof.

1. An assembly, comprising:
a substrate; and
a plurality of electrodes distributed across at least an active touchscreen area of the substrate;
wherein at least one electrode of the plurality of electrodes comprises a group of redundant electrode lines electrically coupled to one another at multiple points along the at least one electrode.

2. The touchscreen display assembly of claim 1, further comprising one or more bridging elements to couple between the electrode lines between ends of the at least one electrode.

3. The touchscreen display assembly of claim 1, wherein the group of redundant electrode lines comprises electrode lines having a line width of 10 micrometers or less.

4. The touchscreen display assembly of claim 1, wherein the plurality of electrodes have a line density of 10% or less in the active touchscreen area.

5. The touchscreen display assembly of claim 1, wherein the group of electrode lines of the at least one electrode are substantially parallel to one another.

6. The touchscreen display assembly of claim 5, wherein a distance between each of the redundant electrode lines is between five times and fifty times the width of an individual redundant electrode line.

7. A method of forming a touchscreen display assembly, comprising:
forming a plurality of touchscreen electrodes distributed across at least an active touchscreen area of a substrate;
wherein at least one electrode of the plurality of touchscreen electrodes comprises a group of redundant electrode lines electrically coupled to an external electrical circuit connection, the redundant electrode lines further coupled to one another remote from the external electrical circuit connection.

8. The method of forming a touchscreen display assembly of claim 7, further comprising overlaying the touchscreen substrate on a display.

9. The method of forming a touchscreen display assembly of claim 7, further comprising coupling electrode lines of the group of redundant electrode lines using bridging elements positioned between ends of the at least one electrode.

10. The method of forming a touchscreen display assembly of claim 7, wherein the the at least one electrode comprises electrode lines having a line width of 10 micrometers or less.

11. The method of forming a touchscreen display assembly of claim 7, wherein the plurality of touchscreen elements have a line density of 10% or less in the active touchscreen area.

12. The method of forming a touchscreen display assembly of claim 7, wherein the electrode lines of the at least one electrode are substantially parallel to one another.

13. The method of forming a touchscreen display assembly of claim 12, wherein a distance between electrode lines of the at least one electrode is between five times and fifty times the width of an individual electrode line.

14. The method of forming a touchscreen display of claim 7, wherein forming a plurality of touchscreen electrodes comprises printing the electrodes on the substrate.

15. An electronic device, comprising:
a display; and
a touchscreen comprising a plurality of touchscreen electrodes distributed across at least an active touchscreen area of a substrate overlaying the display;
wherein at least one electrode of the plurality of touchscreen electrodes comprises a group of redundant electrode lines electrically coupled to an external electrical circuit connection, the redundant electrode lines further coupled to one another remote from the external electrical circuit connection.

16. The electronic device of claim 15, further comprising one or more bridging elements coupling the redundant electrode lines between ends of the at least one electrode.

17. The electronic device of claim 15, wherein the plurality of touchscreen electrodes comprise elements having a line width of 10 micrometers or less.

18. The electronic device of claim 15, wherein the plurality of touchscreen electrodes have a line density of 10% or less in the active touchscreen area.

19. The electronic device of claim 15, wherein the redundant electrode lines of the at least one electrode are substantially parallel to one another.

20. The electronic device of claim 19, wherein the distance between the redundant electrode lines is between five times and fifty times the width of an individual redundant electrode line.

21. A method of forming an electronic device, comprising:
forming a display; and
forming a touchscreen overlaying the display comprising a plurality of touchscreen electrodes distributed across at least an active touchscreen area of a substrate overlaying the display;
wherein at least one electrode of the plurality of touchscreen electrodes comprises a group of three or less redundant electrode lines electrically coupled to an external electrical circuit connection and further coupled to one another remote from their external electrical circuit connection.
